(19) United States
(12) Patent Application Publication
(10) Pub. No.: US 2002/0149087 A1
(43) Pub. Date: Oct. 17, 2002

(54) Semiconductor filter system and signal frequency control method

(75) Inventor: Koji Okada, Kasugai (JP)

Correspondence Address: ARENT FOX KINTNER PLOTKIN & KAHN, PLLC, Suite 400, 1050 Connecticut Avenue, N.W., Washington, DC, 20036-5339, US

(73) Assignee: FUJITSU LIMITED

(21) Appl. No.: 10/093,822

(22) Filed: Mar. 11, 2002

(30) Foreign Application Priority Data
Mar. 13, 2001 (JP) 2001-070563

(51) Int. Cl. H01L 29/00

(52) U.S. Cl. 257/533

(57) ABSTRACT

A filter circuit which can automatically adjust a time constant is provided.

A time constant of a filter circuit is adjusted by supplying, to the filter circuit, a control signal for controlling an oscillation circuit to output a signal of a predetermined frequency. Since the time constant of filter circuit is automatically adjusted, the adjusting work which hereto has been required for tuning filter circuits can be eliminated and thereby the manufacturing process of the filter circuit or semiconductor device can be simplified and the manufacturing time can be remarkably shortened.

### BACKGROUND OF THE INVENTION

The present invention relates to a systems and methods for a filter circuit for use, for example, in a communication apparatus, an audio apparatus or a storage such as HDD or MO.

A filter circuit is used for selecting a particular frequency and eliminating noise in the communication apparatus and audio apparatus. For example, a low-pass filter allows a low frequency signal to pass, while a high-pass filter allows a wide frequency signal to pass and a band-pass filter allows the signal of a particular frequency band to pass.

In recent years, electronic devices have been required to perform at a higher accuracy and filter circuits used in electronic circuits mounted in electronic devices are also required to have a higher accuracy.

Further, the integration of electronic circuits is has accelerated to where such technologies are also adapted to filter circuits.

However, with the integration of electronic circuits, fluctuation of the electronic circuits occurs during the manufacturing process of the electronic circuits. In order to obtain and maintain the higher accuracy of electronic apparatuses, such fluctuation must be compensated with adjustment work after the manufacture of the electronic circuits.

FIG. 1 illustrates a first low-pass filter of the related art. This low-pass filter is a primary low-pass filter composed of a capacitor 1 having a capacitance value C and a resistor 2 having a resistance value R. The cut-off frequency fc of the low-pass filter is expressed as the formula 1.

[Formula 1]

fc=1/(2πCR)

However, with integration of a filter circuit, fluctuation of 10% to several tens of percent is generated in the capacitance value C and the resistance value R in the manufacturing process. With fluctuation of this capacitance value C and resistance value R, fluctuation of several tens of percent or higher is also generated in the cutoff frequency of the filter circuit. In order to compensate for an error due to the fluctuation, adjustment must be performed, for example, with laser trimming. The laser trimming entails a process where a resistance value near to 10 Ω can be generated, for example, by previously generating 15 resistors of 10 Ω to generate a resistance of 100 Ω and thereafter disconnecting several resistors of 15 resistors with the laser beam.

FIG. 2 illustrates a second low-pass filter of the related art. This second low-pass filter does not contain fixed resistors such as the first low-pass filter of the related art illustrated in FIG. 1, but uses a variable resistor 4. Use of variable resistor enables adjustment of error due to the fluctuation in the manufacturing process.

In the second low-pass filter of the related art, laser trimming is unnecessary unlike the first low-pass filter of the related art. However, an adjustment to obtain the desired resistance value by changing a resistance value of the variable resistor is necessary.

FIG. 3 illustrates a third low-pass filter of the related art. Unlike the variable resistor such as the second low-pass filter of the related art, a transistor 6 is used. The resistance of transistor can be varied by controlling a voltage applied to the transistor in order to adjust the error due to the fluctuation generated in the manufacturing process. In the third low-pass filter of the related art, laser trimming is unnecessary as in the case of the second low-pass filter of the related art. However, an adjustment to obtain the desired resistance value by changing the voltage applied to the transistor must be executed.

As explained above, even in any type of filter circuit of the related art, since an error generated due to the fluctuation in the manufacturing process is compensated, adjustment work after the manufacturing process is required. This adjustment work requires time and effort, resulting in a problem that the manufacturing time and cost are increased.

According to the present invention, the time constant of the filter circuit can be adjusted by supplying a control signal to the filter circuit to control the oscillation circuit to output a signal of the predetermined frequency. As explained above, since the time constant of the filter circuit is automatically adjusted, the adjusting work of the filter circuit which has been required in the related art can be now eliminated, moreover the manufacturing process for the filter circuit or semiconductor device can be simplified and the manufacturing time can be remarkably shortened.

Particularly, in the present invention, it is effective that an exclusive PLL circuit is provided to supply, to the filter circuit, a control voltage or a control current for controlling the voltage controlled oscillator when the PLL circuit is locked. Namely, the time constant of the filter circuit is controlled by utilizing the control voltage or control current for adjusting the oscillation frequency of the voltage control circuit in the PLL circuit. Thereby, fluctuation of the time constant due to the manufacturing process of the filter circuit or the like can be corrected and the filter circuit can output the predetermined frequency signal in the desired cut-off frequency at the design stage.

In regard to the above explanation, the following items are disclosed in the present invention.

### SUMMARY OF THE INVENTION

The present invention discloses a filter circuit for adjusting a time constant based on a signal for controlling an oscillation circuit that is characterized in that a time constant of the filter circuit and a time constant of the oscillation circuit are in the relationship of integer times.

Moreover, the present invention provides a semiconductor device comprising an oscillation circuit for outputting signals of different frequencies based on an input signal and a filter circuit for allowing predetermined frequencies to pass, characterized in that a time constant of the filter circuit is adjusted based on the input signal.

According to the filter circuit or semiconductor device of the present invention, a time constant of the filter circuit is adjusted by supplying, to the filter circuit, a control signal for controlling the oscillation circuit to output the signal of the predetermined frequency. As explained above, the time constant of the filter circuit is automatically adjusted and, therefore, the adjustment work of the filter circuit which was previously required is no longer necessary. Therefore, the manufacturing process of the filter circuit and semiconductor device can be simplified and the manufacturing time can be remarkably shortened.

### BRIEF DESCRIPTION OF THE DRAWINGS

FIG. 1 is a diagram illustrating a first low-pass filter circuit of the related art.

FIG. 2 is a diagram illustrating a second low-pass filter circuit of the related art.

FIG. 3 is a diagram illustrating a third low-pass filter circuit of the related art.

FIG. 4 is a diagram illustrating a first embodiment of the present invention.

FIG. 5 is a diagram illustrating a second embodiment of the present invention.

FIG. 6 is a diagram illustrating a third embodiment of the present invention.

FIG. 7 is a diagram illustrating a fourth embodiment of the present invention.

FIG. 8 is a diagram illustrating a fifth embodiment (1) of the present invention.

FIG. 9 is a diagram illustrating a fifth embodiment (2) of the present invention.

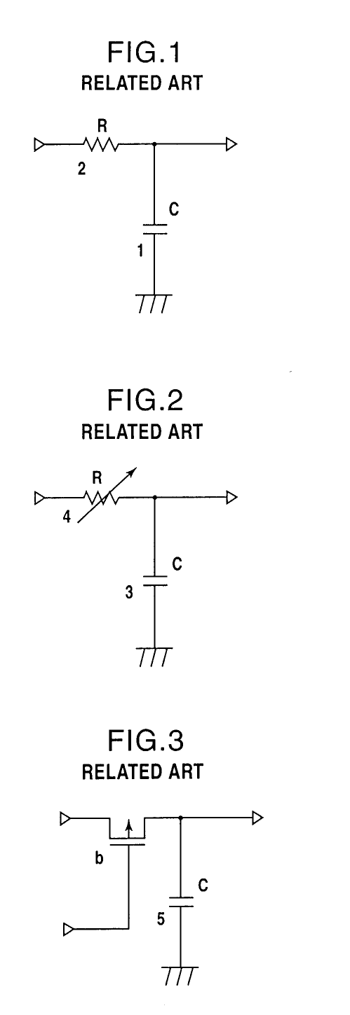

### DETAILED DESCRIPTION OF THE PREFERRED EMBODIMENTS

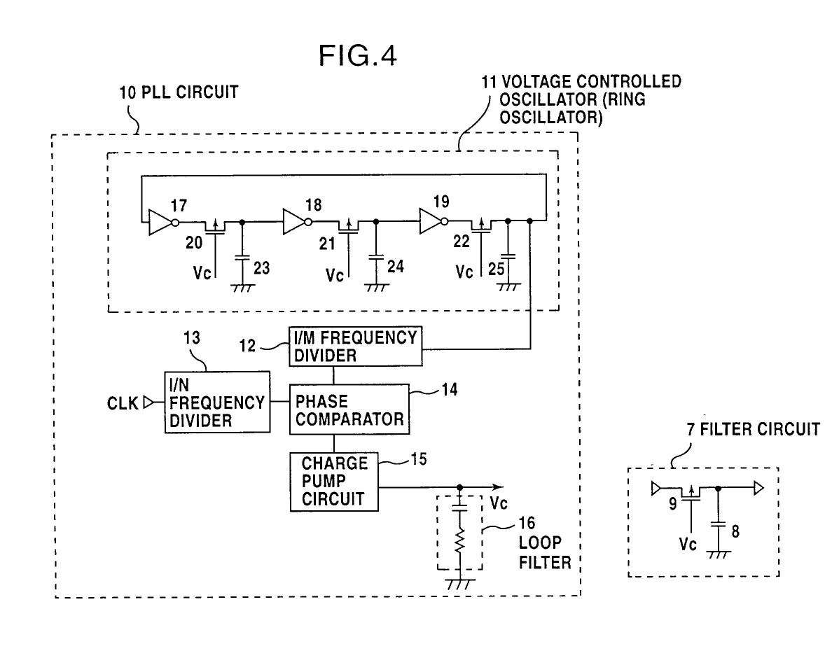

FIG. 4 illustrates a first embodiment of the present invention.

In FIG. 4, a control voltage generated in the PLL (Phase Locked Loop) circuit 10 is supplied to a low-pass filter circuit 7. The control voltage Vc controls the cut-off frequency of the filter circuit 7 by controlling the gate voltage of transistor 9 of the filter circuit 7.

The PLL circuit 10 contains a voltage controlled oscillator 11, a 1/M frequency divider 12, a 1/N frequency divider 13, a phase comparator 14, a charge pump circuit 15 and a loop-filter 16.

The signal generated in the voltage controlled oscillator 11 is supplied to the 1/M frequency divider 12, divided in the frequency to 1/M times (M is an integer) and is then supplied to the phase comparator 14. Also, a reference clock CLK is supplied to the 1/N frequency divider 13, divided in the frequency to 1/N times (N is an integer) and is then supplied to the phase comparator 14. In the phase comparator 14, the 1/M frequency divided signal is compared with the 1/N frequency divided reference clock and a comparison signal depending on the phase difference is then supplied to the charge pump circuit 15. The charge pump circuit 15 supplies a signal based on the comparison signal to the loop filter 16. The loop filter 16 supplies a signal, smoothed by eliminating higher frequency element noise or the like, to the voltage controlled oscillator 11.

The voltage controlled oscillator 11 includes a self-exciting type oscillator and also oscillates a frequency changed signal based on the feedback signal (not shown) from the loop filter 16.

In the first embodiment of the present invention, the voltage controlled oscillator 11 contains a ring oscillator in which the odd number of circuits, formed of inverters, transistors and capacitors are loop-connected. An output of the first inverter 17 is connected to one end of the first NMOS transistor 20 and the inputs of the first capacitor 23 and second inverter 18 are connected to the other end of the first NMOS transistor 20. An output of the second inverter 18 is connected to one end of the second NMOS transistor 21 and the inputs of the second capacitor 24 and third inverter 19 are connected to the other end of the second NMOS transistor 21. An output of the third inverter 19 is connected to one end of the third NMOS transistor 22, while the inputs of the third capacitor 25 and first inverter 17 are connected to the other end of the third NMOS transistor 22. A feedback signal (not shown), namely the control voltage Vc is fed, from the loop filter 16, to each gate of the first NMOS transistor 20, second NMOS transistor 21 and third NMOS transistor 22. These NMOS transistors are adjusted in the resistance values based on the control voltage Vc. Namely, these NMOS transistors function as the variable resistors.

Meanwhile, the filter circuit 7 is a low-pass filter formed of an NMOS transistor 9 and a capacitor 8.

The PLL circuit 10 operates to result in a lock condition where the frequency or phase of the signal from the voltage controlled oscillator (e.g., ring oscillator) 11 is matched with that of the reference clock. Here, the resistance of each NMOS transistor of the ring oscillator 11 is defined as Rt and the capacitance of each capacitor as C. In the lock condition, the signal oscillation period of the ring oscillator 11 is adjusted with the control voltage Vc to be proportional to C*Rt.

Therefore, the oscillation frequency of the ring oscillator 11 is adjusted to be proportional to 1/(C*Rt). When the control voltage Vc is increased to make the Rt value smaller, the oscillation frequency of the ring oscillator 11 becomes larger. On the contrary, when the control voltage Vc is lowered to increase Rt, the oscillation frequency of the ring oscillator 11 becomes small. For example, when Rt (or C) increases by about 10% due to fluctuation generated in the manufacturing process, the control voltage Vc outputted from the loop filter 16 becomes large and a resistance value of each NMOS transistor is controlled to decrease Rt as much as 10%.

As explained above when the PLL circuit 10 is in the lock condition, the frequency of the signal oscillated by the ring oscillator 11 is stabilized in proportion to 1/(C*Rt). Namely, when the PLL circuit 10 is in the lock condition, fluctuation of C*Rt is corrected and thereby the desired C*Rt can be obtained. Here, the oscillation frequency of the ring oscillator 11 has a value proportional to 1/(C*Rt) including no fluctuation. As explained above, when the PLL circuit 10 is in the lock condition, the time constant of ring oscillator 11 becomes the desired value without any fluctuation.

Here, the cut-off frequency of filter circuit 7 is proportional to 1/(C*Rt) like the oscillation frequency of the ring oscillator 11 (refer to formula 1). Therefore, the control voltage Vc for controlling the time constant of the ring oscillator 11 can be used for the filter circuit 7. The time constant of filter circuit 7 can also be adjusted as in the case of the ring oscillator 11 by supplying the control voltage Vc, in the condition that the PLL circuit 10 is locked, to the gate of transistor 9 of filter circuit 7. Accordingly, the filter circuit 7 can generate the cut-off frequency with the desired time constant without any fluctuation.

The PLL circuit 10 and the filter circuit 7 in the first embodiment of the present invention can be formed on the same chip. Therefore, the manufacturing process, operation environment and operating condition or the like are identical and the transistor and capacitor formed on the chip are in the same fluctuating condition. Therefore, the fluctuation of the filter circuit 7 can also be corrected by using, as input to the filter circuit 7, the control voltage Vc outputted from the loop filter 16 of the PLL circuit 10, for correcting such fluctuating condition. Namely, the time constant of filter circuit 7 can be corrected as in the case of the time constant of the ring oscillator 11 by controlling the resistance value of the NMOS transistor 9 of the filter circuit 7 with the control voltage Vc for controlling the resistance values of the NMOS transistors 20, 21 of the ring oscillator 11.

As explained above, the time constant of filter circuit 7 can be adjusted automatically by supplying, to the filter circuit 7, the control voltage Vc supplied to the ring oscillator 11 when the PLL circuit 10 is locked. Thereby, the filter 7 can be operated at the desired cut-off frequency predetermined at the time of design of the filter circuit 7 and the performance of filter circuit 7 can also be improved.

In the first embodiment of the present invention, the NMOS transistors are used for the ring oscillator 11 and filter circuit 7, but PMOS transistor, CMOS transistor, bipolar transistor or other various transistor or transistor-like devices may also be used.

Moreover, in this first embodiment of the present invention, the PLL circuit 10 and filter circuit 7 are formed on the same chip. However, if a relative error between the capacitance value of the PLL circuit and the capacitance value of the filter circuit is small, the PLL circuit and the filter circuit may be formed on individual chips when the relative error of capacitance values is small.

Moreover, in the first embodiment of the present invention, the PLL circuit also operates as a frequency multiplier to multiply the reference clock CLK to M/N times. Therefore, the cut-off frequency can be changed as desired by changing the frequency dividing ratio. For example, when the frequency dividing ratio is set with a resistor, the cut-off frequency can be easily changed to a higher accuracy only by changing the frequency dividing ratio in the resistor. When it is desired to raise the cut-off frequency by up to two times, it can be attained by reducing, to a half, the frequency dividing ratio designated with the 1/M frequency divider 12. Therefore, the desired cut-off frequency can be attained only by setting the frequency dividing ratio reduced to ½ to the resistor.

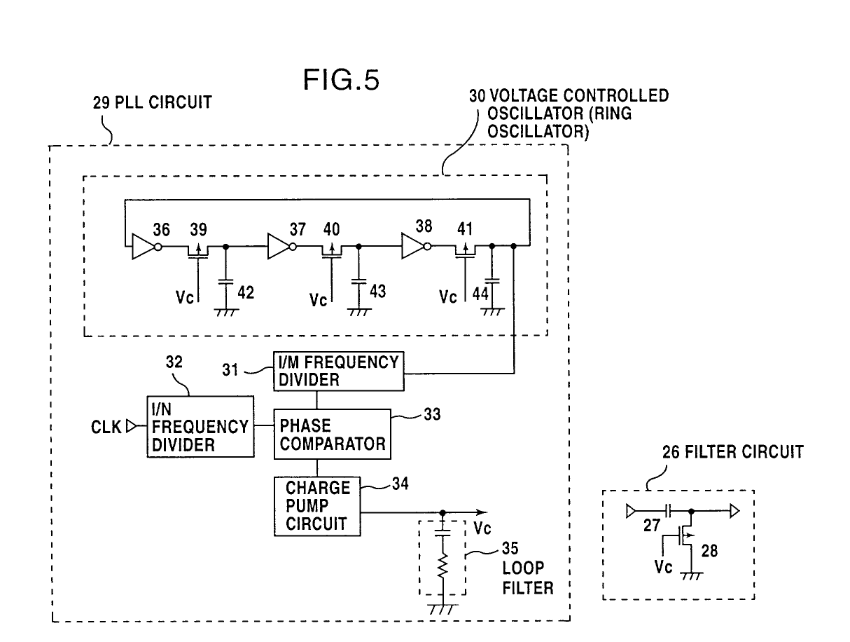

FIG. 5 illustrates the second embodiment of the present invention.

As in the case of FIG. 4, the control voltage Vc generated in the PLL circuit 29 is supplied to the transistor 28 of the filter circuit 26 to control the filter circuit 26 cut-off frequency in FIG. 5.

The second embodiment of the present invention is different from the first embodiment thereof in the point that the filter circuit 26 is formed of a high-pass filter formed, for example, by a transistor 28 and a capacitor 27, and the other portions are identical.

Even in the second embodiment of the present invention, the filter circuit 26 can generate the desired cut-off frequency with the time constant without any fluctuation by using the control voltage Vc when the PLL circuit 29 is locked for the filter circuit 26.

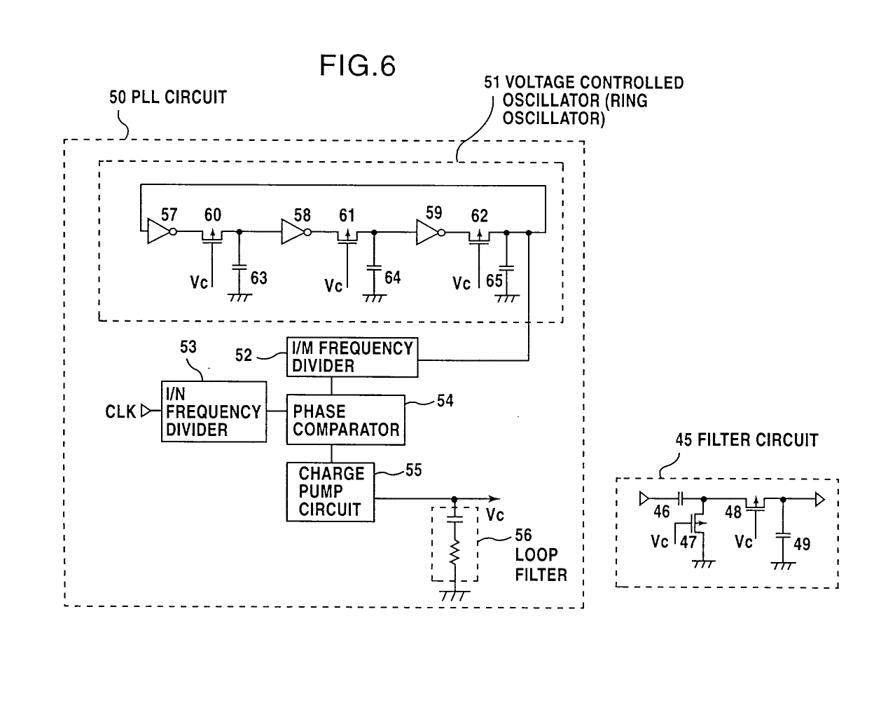

FIG. 6 illustrates the third embodiment of the present invention.

In FIG. 6, the control voltage Vc generated in the PLL circuit 50 is supplied, as in the case of FIG. 4, to the transistors 47 and 48 of the filter circuit 45 to control the cut-off frequency of the filter circuit 45. Capacitors 46 and 49 are connected to the transistors 47 and 48 to provide band pass capabilities.

The primary difference in the third embodiment of the present invention from the first embodiment thereof, is that a band-pass filter is used as the filter circuit 45 but the other portions are identical.

In the third embodiment of the present invention, the filter circuit 45 can generate the desired cut-off frequency with the time constant without any fluctuation by using, for the filter circuit 45, the control voltage Vc when the pLL circuit 50 is locked.

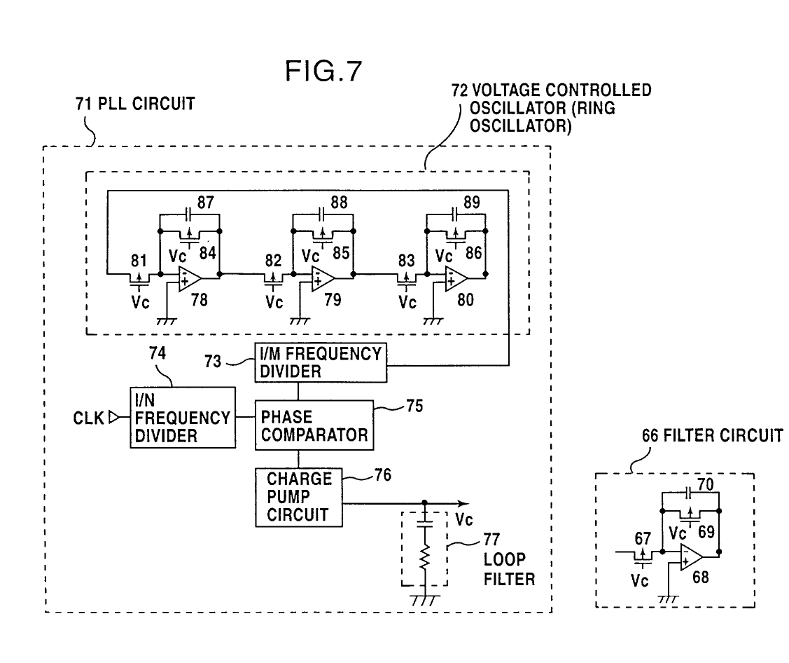

FIG. 7 illustrates the fourth embodiment of the present invention.

In FIG. 7, the control voltage Vc generated in the PLL circuit 71 is supplied, as in the case of FIG. 4, to the transistors 67 and 69 of the filter circuit 66 to control the cut-off frequency of the filter circuit 66.

The primary difference of the fourth embodiment of the present invention from the first embodiment thereof is that the filter circuit 66 is not a passive filter but an active filter provided with an operational amplifier 68. Moreover, the structure of the ring oscillator of PLL circuit 71 is changed depending on change of the filter circuit 66. In the fourth embodiment of the present invention, since the active filter provided with the operational amplifier is used in the filter circuit 66, the voltage signal can be amplified depending on the gain.

The filter circuit 66 is structured with a first NMOS transistor 67 and operational amplifier 68 wherein one end of the first NMOS transistor 67 is connected to an inverted input and thereby the reference voltage is supplied to the non-inverted input, a second NMOS transistor 69 for feeding back an output of the operational amplifier 68 to the inverted input and a capacitor 70.

As the ring oscillator 72, the circuit of the same structure as the filter circuit 66 is loop-connected in the odd number stages.

Even in the fourth embodiment of the present invention, fluctuation generated in the manufacturing processes of the first NMOS transistor, second NMOS transistor, capacitor in the ring oscillator 72 and of the elements forming the operational amplifier is corrected as in the case of the other embodiment of the present invention, and the control voltage Vc for canceling noise due to fluctuation of power supply is also supplied to the filter circuit 66. Therefore, the filter circuit 66 generates the desired cut-off frequency to output the predetermined frequency signal by correcting fluctuation thereof and canceling noise due to fluctuation of power supply with the control voltage Vc.

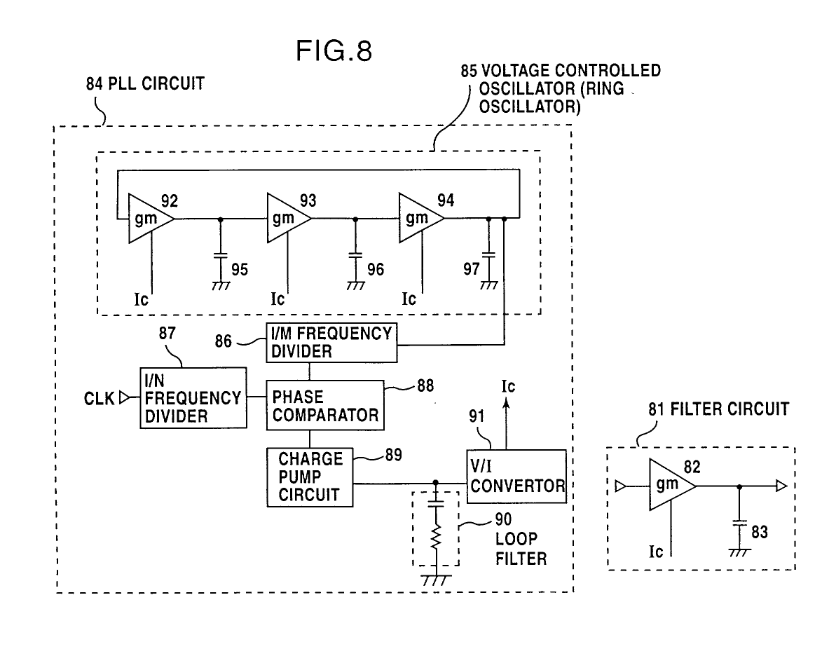

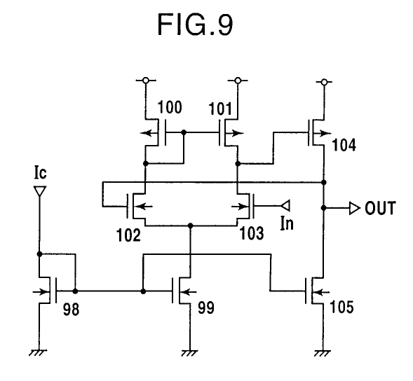

FIG. 8 and FIG. 9 illustrate the fifth embodiment of the present invention.

In FIG. 8, the signal generated in the PLL circuit 84 is supplied to the filter circuit 82, as in the case of FIG. 4, to control the cut-off frequency of the filter circuit 81.

Moreover, even in the fifth embodiment of the present invention, the filter circuit is not a passive filter but an active filter as in the case of the fourth embodiment of the present invention. However, in the fifth embodiment of the present invention, the filter circuit 81 provided with a current control type gm amplifier (mutual conductance type amplifier circuit) 82 in substitution for the earlier filter circuit provided with the voltage control type operational amplifier. Therefore, the PLL circuit 84 is provided with a voltage-current converter 91. Moreover, the circuit of the same structure as the filter circuit provided with the gm amplifier is used in the ring oscillator 85 of the PLL circuit 84.

The filter circuit 81 is structured with the gm amplifier is used in the ring oscillator 85 of the PLL circuit 84.

The ring oscillator 85, the circuit of the same structure as the filter circuit 81, is loop-connected in odd number stages.

At the output of the loop-filter 90 of the PLL circuit 84, the voltage-current converter 91 is allocated to convert a voltage signal outputted from the loop-filter 90 to a current signal and supply such current signal as the control current Ic to the ring oscillator 85. Here, it is possible to consider that the voltage controlled oscillator is formed through the combination of the voltage-current converter 91 and ring oscillator 85.

In the fifth embodiment of the present invention, a control signal Ic for correcting the fluctuation generated in the manufacturing processes of the elements forming the gm amplifier and the capacitor and also for canceling noise generated with fluctuation of power supply is also supplied to the filter circuit 81. Therefore, the filter circuit 81 corrects its own fluctuation and cancels noise from fluctuation of power supply with the control current Ic in view of generating the cut-off frequency and outputting the predetermined frequency signal.

FIG. 8 illustrates an example of the gm amplifier used in the present invention.

The gm amplifier illustrated in FIG. 8 is structured with the PMOS transistors 98, 99, 102, 103, 105 and NMOS transistors 100, 101 and 104.

The PMOS transistor 98 and PMOS transistor 99 form a current mirror circuit. A current flowing into the PMOS transistor 99 is controlled and changed depending on the change of the current flowing into the PMOS transistor 98. A current flowing into the PMOS transistor 102 and PMOS transistor 103 changes depending on the change of the current flowing into the PMOS transistor 99 and thereby a current outputted from the output stage also changes. As explained above, in the gm amplifier illustrated in FIG. 9, and output current changes depending on the control current Ic. The fact is an output current, outputted from the gm amplifier, changes, based on the control current Ic, is identical to the resistance of gm amplifier changes, depending on the control current Ic. Therefore, the gm amplifier as a whole can be considered as a resistor. Accordingly, even in the fifth embodiment of the present invention, the time constant of the filter circuit 81 can be adjusted based on the control current Ic.

The gm amplifier illustrated in FIG. 9 is only an example and the gm amplifier of various desired structures can also be adapted to the present invention.

While this invention has been described in conjunction with specific embodiments thereof, it is evident that many alternatives, modifications and variations will be apparent to those skilled in the art. Accordingly, preferred embodiments of the invention as set forth herein are intended to be illustrative and not limiting. Thus, there are changes that may be made without departing from the spirit and scope of the invention.

What is claimed is:

1. A filter circuit having a time constant, for connection to an oscillator circuit, said filter circuit comprising:
adjusting means for adjusting the time constant of the filter circuit; and
coupling means for coupling the filter circuit to an oscillator circuit;
wherein, a time constant of the oscillation circuit and the filter circuit is adjusted based on a control signal for controlling the oscillation circuit, and wherein the time constant of the filter circuit and a time constant of the oscillation circuit are proportional.

2. The filter circuit according to claim 1 including:
a capacitor, and
wherein the adjusting means includes an adjustable resistance element, the resistance element being controlled with the control signal.

3. The filter circuit according to claim 2, wherein the adjusting means further includes an operational amplifier.

4. The filter circuit according to claim 1 including:
a capacitor, and
wherein the adjusting means includes a current control amplifier, the amplifier being controlled by the control signal.

5. The filter circuit according to claim 1, wherein the oscillation circuit includes a ring oscillator having a plurality of connected circuits, at least one of the connected circuits having a similar circuit structure as the filter circuit.

6. The filter circuit according to claim 1, wherein the filter circuit is either a low-pass filter circuit, a high-pass filter circuit or a band-pass filter circuit.

7. A filter circuit having a time constant for connection to to a PLL circuit, the PLL circuit having an oscillator, said filter circuit comprising:
adjusting means for adjusting a time constant of the filter circuit; and
coupling means for coupling the filter circuit to a PLL circuit;
wherein, the time constant of the filter circuit is adjusted based on a control signal which controls the oscillator when the PLL circuit is locked to allow the filter circuit to pass at least one predetermined frequency.

8. The filter circuit according to claim 7, wherein the PLL circuit includes a frequency divider, and
wherein at least one cut-off frequency is controlled based on a frequency dividing ratio of the frequency divider.

9. The filter circuit according to claim 7, wherein the adjusting means includes an adjustable resistance element, the resistance of the resistance element determining the time constant of the filter circuit and is controlled by the control signal.

10. The filter according to claim 7, further including a capacitor.

11. The filter circuit according to claim 10, further wherein the adjusting means further includes an operational amplifier.

12. The filter circuit according to claim 7 including:
a capacitor, and
wherein the adjusting means includes a current control amplifier, the amplifier being controlled with the control signal.

13. The filter circuit according to claim 7, wherein the oscillation circuit includes a ring oscillator having a plurality of connected circuits, at least one of the connected circuits having a similar circuit structure as the filter circuit.

14. The filter circuit according to claim 7, wherein the filter circuit is either a low-pass filter circuit, high-pass filter circuit, or a band-pass filter circuit.

15. A semiconductor device comprising:
an oscillation circuit for outputting signals of different frequencies based on an input signal; and
a filter circuit, coupled to the oscillation circuit, for allowing a signal of at least one predetermined frequency to pass,
wherein the input signal is supplied to the filter circuit, the input signal being a control signal that adjusts a time constant of the filter circuit.

16. The semiconductor device according to claim 15, wherein the filter circuit comprises:
a resistance element controlled by the control signal; and
a capacitor.

17. The semiconductor device according to claim 16, wherein the filter circuit further includes an operational amplifier.

18. The semiconductor device according to claim 15, wherein the filter circuit comprises:
a current control amplifier controlled by the control signal; and
a capacitor.

19. The semiconductor device according to claim 15, wherein the oscillation circuit includes a ring oscillator having a plurality of connected circuits, at least one of the connected circuits having a similar circuit structure as the filter circuit.

20. The semiconductor device according to claim 15, wherein the filter circuit is either a low-pass filter circuit, a high-pass filter circuit, or a band-pass filter circuit.

21. A semiconductor device comprising:
an oscillation circuit for outputting signals of different frequencies based on an input signal;
a comparison circuit for comparing the signals output by the oscillation circuit with a clock signal to output a comparison result as an input signal to the oscillation circuit; and
a filter circuit that allows a signal of at least one of a predetermined frequency to pass, wherein, the input signal is supplied as a control signal to the filter circuit when the signal outputted from the oscillation circuit is stabilized.

22. A filter system comprising:
an oscillation unit for outputting signals of different frequencies based on an input signal; and
a filter unit that allows a signal of at least one predetermined frequency to pass, wherein a time constant of the filter unit is adjusted based on the input signal and the filter unit outputs at least one signal of the predetermined frequencies.

23. The filter system according to claim 22, wherein the oscillation unit is a voltage control oscillation unit or a current control oscillation unit.

24. A filter system comprising:
an oscillation unit having an oscillator that outputs signals of different frequencies based on an input signal and a frequency divider;
a frequency divider; and
a filter unit that allows at least one signal of a predetermined frequency to pass, wherein a cut-off frequency of the filter unit is controlled based on a frequency dividing ratio of the frequency divider.

25. A method for controlling the filtering of oscillating signals, comprising the steps of:
controlling an oscillator that generates signals of different frequencies by a control signal;
adjusting a time constant of a filtering element on a basis of the control signal; and
outputting, on a basis of a cut-off frequency based on the adjusted time constant, at least one signal of a predetermined different frequency.
